(19) United States
(12) Patent Application Publication
(10) Pub. No.: US 2012/0091508 A1
(43) Pub. Date: Apr. 19, 2012

(54) COMPOUND SEMICONDUCTOR DEVICE

(75) Inventor: Hironori AOKI, Niiza-shi (JP)

(73) Assignee: Sanken Electric Co., Ltd., Niiza-shi (JP)

(21) Appl. No.: 13/204,968

(22) Filed: Aug. 8, 2011

(30) Foreign Application Priority Data
Aug. 9, 2010 (JP) 2010-178778

(51) Int. Cl. H01L 29/778

(52) U.S. Cl. 257/194; 257/E29.246

(57) ABSTRACT

A compound semiconductor device includes: a compound semiconductor layer; a source electrode; a drain electrode; a gate electrode; a field plate; and a low-conductivity region. The low-conductivity region is arranged within a region immediately below the field plate in a region where the two-dimensional carrier gas layer is formed, and has lower conductivity than a region above which the field plate or the gate electrode is not arranged in the region where the two-dimensional carrier gas layer is formed.

### CROSS-REFERENCE TO RELATED APPLICATION

This application is based upon and claims the benefit of priority from Japanese Patent Application No. 2010-178778, filed on Aug. 9, 2010; the entire contents of which are incorporated herein by reference.

### BACKGROUND OF THE INVENTION

1. Field of the Invention

The present invention relates to a compound semiconductor device in which a two-dimensional carrier gas layer is formed.

2. Description of the Related Art

For a light emitting element such as a semiconductor laser and a light emitting diode (LED), a photodetector such as a photodiode, a high voltage power device, or the like, there is used a compound semiconductor device composed, for example, of a III-V group nitride semiconductor and the like. A typical III-V group nitride semiconductor is represented by AlₓIn_{y}Ga_{1-x-y}N (0≦x≦1, 0≦y≦1, 0≦x+y≦1), and for example, is aluminum nitride (AlN), gallium nitride (GaN), indium nitride (InN), and the like. A heterojunction surface is formed on an interface between a carrier travel layer and a carrier supply layer, which are made of nitride semiconductors different from each other in band gap energy. In the carrier travel layer in the vicinity of the heterojunction surface, a two-dimensional carrier gas layer as a current path (channel) is formed.

A bias electric field, which is generated in the case where a voltage is applied between a drain electrode and source electrode of the compound semiconductor device, concentrates on a drain electrode-side end portion of a gate electrode of the compound semiconductor device. By relieving such concentration of the bias electric field, a withstand voltage of the compound semiconductor device can be enhanced. For example, there has been proposed a method for relieving the concentration of the bias electric field between the gate electrode and the drain electrode by forming a reduced charge region in the two-dimensional carrier gas layer (WO 2007/109265 A2).

### SUMMARY OF THE INVENTION

However, the above-described reduced charge region is regarded as a resistance component connected between the source electrode and the drain electrode. Therefore, there has been a problem that there rises an ON-resistance during the time when the compound semiconductor device is operating.

In consideration of the foregoing problem, it is an object of the present invention to provide a compound semiconductor device, in which the concentration of the bias electric field in the end portion of the gate electrode is relieved, and the increase of the ON-resistance during such an operating time is suppressed.

A compound semiconductor device according to a first aspect of the present invention includes: a compound semiconductor layer; a source electrode; a drain electrode; a gate electrode; a field plate; and a low-conductivity region. The compound semiconductor layer has a carrier supply layer and a carrier travel layer in which a two-dimensional carrier gas layer is formed in a vicinity of an interface with the carrier supply layer. The source electrode and the drain electrode are arranged on a principal surface of the compound semiconductor layer. The gate electrode is arranged on the principal surface between the source electrode and the drain electrode. The field plate is arranged above the principal surface between the gate electrode and the drain electrode. The low-conductivity region is arranged within a region immediately below the field plate in a region where the two-dimensional carrier gas layer is formed, and has lower conductivity than a region above which the field plate or the gate electrode is not arranged in the region where the two-dimensional carrier gas layer is formed.

In accordance with the first aspect of the present invention, there can be provided the compound semiconductor device, in which the concentration of the bias electric field in the end portion of the gate electrode is relieved, and the increase of the ON-resistance during the operating time is suppressed.

### BRIEF DESCRIPTION OF THE DRAWINGS

FIG. 1 is a schematic cross-sectional view illustrating a structure of a compound semiconductor device according to a first embodiment.

FIG. 2 is a process cross-sectional view for explaining a manufacturing method of the compound semiconductor device according to the first embodiment (No. 1).

FIG. 3 is a process cross-sectional view for explaining the manufacturing method of the compound semiconductor device according to the first embodiment (No. 2).

FIG. 4 is a process cross-sectional view for explaining the manufacturing method of the compound semiconductor device according to the first embodiment (No. 3).

FIG. 5 is a process cross-sectional view for explaining the manufacturing method of the compound semiconductor device according to the first embodiment (No. 4).

FIG. 6 is a process cross-sectional view for explaining the manufacturing method of the compound semiconductor device according to the first embodiment (No. 5).

FIG. 7 is a process cross-sectional view for explaining the manufacturing method of the compound semiconductor device according to the first embodiment (No. 6).

FIG. 8 is a process cross-sectional view for explaining the manufacturing method of the compound semiconductor device according to the first embodiment (No. 7).

FIG. 9 is a schematic cross-sectional view illustrating a structure of a compound semiconductor device according to a modification example of the first embodiment.

FIG. 10 is a schematic cross-sectional view illustrating a structure of a compound semiconductor device according to a modification example of the first embodiment.

FIG. 11 is a process cross-sectional view for explaining a manufacturing method of the compound semiconductor device illustrated in FIG. 10.

FIG. 12 is a schematic cross-sectional view illustrating a structure of a compound semiconductor device according to a modification example of the first embodiment.

FIG. 13 is a schematic cross-sectional view illustrating a structure of a compound semiconductor device according to a second embodiment.

FIG. 14 is a process cross-sectional view for explaining a manufacturing method of the compound semiconductor device according to the second embodiment (No. 1).

FIG. 15 is a process cross-sectional view for explaining the manufacturing method of the compound semiconductor device according to the second embodiment (No. 2).

FIG. 16 is a process cross-sectional view for explaining the manufacturing method of the compound semiconductor device according to the second embodiment (No. 3).

FIG. 17 is a process cross-sectional view for explaining the manufacturing method of the compound semiconductor device according to the second embodiment (No. 4).

FIG. 18 is a process cross-sectional view for explaining the manufacturing method of the compound semiconductor device according to the second embodiment of the present invention (No. 5).

FIG. 19 is a process cross-sectional view for explaining the manufacturing method of the compound semiconductor device according to the second embodiment (No. 6).

### DETAILED DESCRIPTION OF THE EMBODIMENTS

Next, a description is made of first and second embodiments with reference to the drawings. In the following description referring to the drawings, the same or similar reference numerals are assigned to the same or similar portions. However, the drawings are schematic, and it should be noted that relationships between thicknesses and planar dimensions, ratios of lengths among the respective portions, and the like are different from the actual ones. Hence, specific dimensions should be determined in consideration of the following description. Moreover, it is a matter of course that, also among the drawings, there are included portions in which dimensional relationships and ratios are different from one another.

Moreover, the first and second embodiments described below illustrate devices and methods for embodying the technical idea of the present invention, and the technical idea of the present invention does not specify shapes, structures, arrangement and the like of constituent components to those described below. The embodiments of the present invention can be added with a variety of alterations within the scope of claims.

### First Embodiment

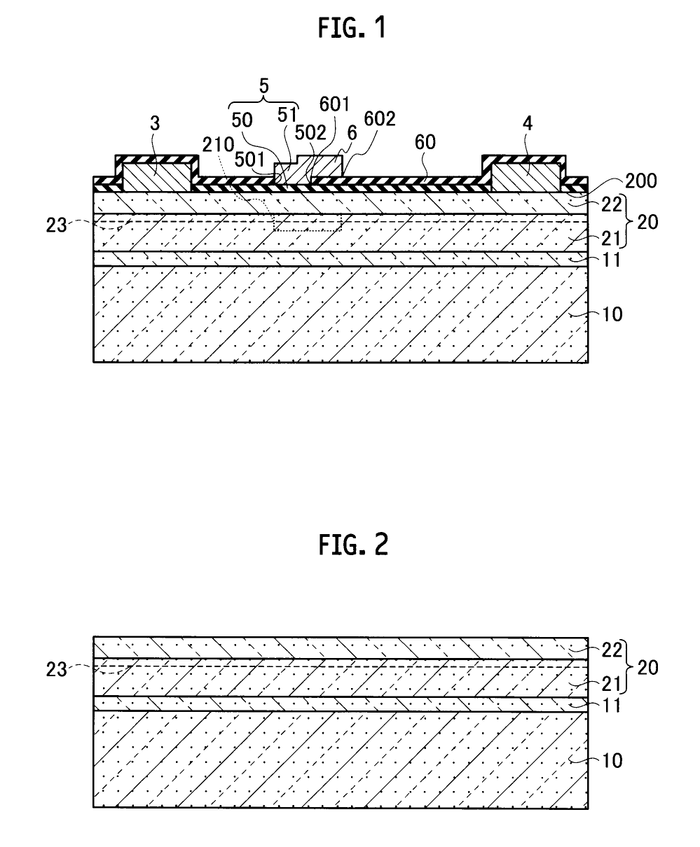

As illustrated in FIG. 1, a compound semiconductor device 1 according to the first embodiment includes: a compound semiconductor layer 20; a source electrode 3 and a drain electrode 4, which are arranged on a principal surface 200 of the compound semiconductor layer 20; a gate electrode 5 arranged on the principal surface 200 between the source electrode 3 and the drain electrode 4; and a field plate 6 arranged on the principal surface 200 while interposing a field insulating film 60 therebetween between the gate electrode 5 and the drain electrode 4.

The compound semiconductor layer 20 includes: a carrier supply layer 22 made of a first nitride compound semiconductor; and a carrier travel layer 21 made of a second nitride compound semiconductor having band gap energy different from that of the first nitride compound semiconductor. In the carrier travel layer 21 in the vicinity of a heterojunction surface between the carrier travel layer 21 and the carrier supply layer 22, a two-dimensional carrier gas layer 23 as a current path (channel) is formed.

In the compound semiconductor device 1, within a region immediately below the field plate 6 in a region of the carrier travel layer 21, where the two-dimensional carrier gas layer 23 is formed, in an upper portion thereof in the region of the carrier travel layer 21, where the two-dimensional carrier gas layer 23 is formed, there is arranged a low-conductivity region 210 having lower conductivity than a region where the field plate 6 or the gate electrode 5 is not arranged. Moreover, also within a region below the gate electrode 5, where the two-dimensional carrier gas layer 23 is formed, the low-conductivity region 210 is arranged. Carrier density of the low-conductivity region 210 approximately ranges from 1×10¹⁷ cm⁻³ to 1×10²⁰ cm⁻³. Meanwhile, carrier density of the region other than the low-conductivity region 210, where the two-dimensional carrier gas layer 23 is formed, are approximately twice or more the carrier density of the low-conductivity region 210, and for example, is 2×10²⁰ cm ⁻³ or more.

The region below the field plate 6, where the low-conductivity region 210 is formed, is a region between a portion below a gate-side end portion 601 of the field plate 6 and a portion below a drain-side end portion 602 thereof Moreover, the region below the gate electrode 5, where the low-conductivity region 210 is formed, is a region between a portion below a source-side end portion 501 of the gate electrode 5 and a portion below a drain-side end portion 502 thereof.

In the compound semiconductor device 1 illustrated in FIG. 1, the gate electrode 5 and the field plate 6 are connected continuously to each other. Therefore, the region where the low-conductivity region 210 is formed is a region where the two-dimensional carrier gas layer 23 is formed between the portion below the source-side end portion 501 of the gate electrode 5 and the portion below the drain-side end portion 602 of the field plate 6.

Moreover, as illustrated in FIG. 1, a buffer layer 11 is formed on a substrate 10, and the compound semiconductor layer 20 is arranged on the buffer layer 11. Moreover, the gate electrode 5 has a structure in which a metal layer 51 and a gate insulating film 50 that is brought into contact with the principal surface 200 of the compound semiconductor layer 20 are stacked on each other. That is to say, a gate electrode structure of the compound semiconductor device 1 illustrated in FIG. 1 is a MIS structure.

For the substrate 10, it is possible to employ a semiconductor substrate such as a silicon (Si) substrate, a silicon carbide (SiC) substrate and a gallium nitride (GaN) substrate, and an insulating substrate such as a sapphire substrate and a ceramic substrate. For example, the silicon substrate easy to increase a diameter thereof is employed for the substrate 10, whereby manufacturing cost of the compound semiconductor device 1 can be reduced.

The buffer layer 11 can be formed by epitaxial growth methods such as an existing metalorganic chemical vapor deposition (MOCVD) method. In FIG. 1, the buffer layer 11 is illustrated as one layer; however, the buffer layer 11 may be formed of a plurality of layers. For example, the buffer layer 11 may be formed into a multilayer-structure buffer in which a first sub-layer made of aluminum nitride (AlN) and a second sub-layer made of gallium nitride (GaN) are alternately stacked on each other. Moreover, in the case where the compound semiconductor device 1 operates as a high electron mobility transistor (HEMT), the buffer layer 11 may be omitted since the buffer layer 11 does not directly affect operations of the HEMT. Moreover, as a material of the buffer layer 11, a nitride semiconductor other than AlN and GaN or a III-V group compound semiconductor may be adopted. A structure in which the substrate 10 and the buffer layer 11 are combined with each other can also be regarded as a substrate. Such structure and arrangement of the buffer layer 11 are decided in response to the material and the like of the substrate 10.

The carrier travel layer 21 arranged on the buffer layer 11 is formed by epitaxially growing, for example, undoped GaN, which is not added with impurities, by the MOCVD method and the like to a thickness approximately ranging from 0.3 to 10 μm. Here, “undoped” stands for that impurities are not added intentionally.

The carrier supply layer 22 arranged on the carrier travel layer 21 is made of a nitride semiconductor, which has a larger band gap than that of the carrier travel layer 21, and is different in lattice constant from the carrier travel layer 21. The carrier supply layer 22 is, for example, a nitride semiconductor represented by AlₓM_{y}Ga_{1-x-y}N (0≦x<1, 0≦y<1, 0≦x+y≦1, M is indium (In), boron or the like), or other compound semiconductors. In the case where the carrier supply layer 22 is AlₓM_{y}Ga_{1-x-y}N, a composition ratio x is preferably 0.1 to 0.4, more preferably 0.3. Moreover, undoped AlₓM_{y}Ga_{1-x-y}N is also employable as the carrier supply layer 22. Furthermore, a nitride semiconductor made of AlₓGa₁₋ₓN added with n-type impurities is also employable for the carrier supply layer 22.

The carrier supply layer 22 is formed on the carrier travel layer 21 by the epitaxial growth using the MOCVD method and the like. The carrier supply layer 22 and the carrier travel layer 21 are different from each other in lattice constant, and accordingly, there occurs piezoelectric polarization owing to a lattice strain. High-density carriers are generated in the vicinity of the heterojunction surface by the piezoelectric polarization and spontaneous polarization owned by crystals of the carrier supply layer 22, and the two-dimensional carrier gas layer 23 is formed. A film thickness of the carrier supply layer 22 is thinner than that of the carrier travel layer 21, approximately ranges from 10 to 50 nm, and for example, is approximately 25 nm.

The gate insulating film 50 is arranged on the principal surface 200 of the compound semiconductor layer 20, and in opening portions individually formed in the gate insulating film 50, the source electrode 3 and the drain electrode 4 are brought into contact with the principal surface 200 of the compound semiconductor layer 20. The source electrode 3 and the drain electrode 4 are formed of metal capable of low resistance contact (ohmic contact) with the compound semiconductor layer 20. Each of the source electrode 3 and the drain electrode 4 is formed, for example, as a stacked body of titanium (Ti) and aluminum (Al), or the like.

The field insulating film 60 is arranged on the gate insulating film 50, the source electrode 3 and the drain electrode 4. The metal layer 51 of the gate electrode 5 is brought into contact with the gate insulating film 50 in an opening portion formed in the field insulating film 60. The metal layer 51 is composed of, for example, a stacked structure of a nickel (Ni) film and a gold (Au) film. That is to say, the gate electrode 5 is formed in such a manner that the Ni film is arranged in contact with the gate insulating film 50, and that the Au film is arranged on the Ni film.

A description is made below of operations of the compound semiconductor device 1, which is illustrated in FIG. 1, at the time of conduction (ON) and at the time of non-conduction (OFF).

First, a description is made of the case where the compound semiconductor device 1 is in a non-conduction (OFF) state, that is to say, in a channel block state. For example, there is considered a case of bias conditions where 600 V is applied to the drain electrode 4, 0 V is applied to the source electrode 3, and an approximate voltage of 0 V to several negative volts is applied to the gate electrode 5 (hereinafter, referred to as “non-conduction bias conditions”). At this time, the same voltage as that to the gate electrode 5 is applied to the field plate 6.

The low-conductivity region 210 is arranged in a channel region located below the field plate 6 and the gate electrode 5, and accordingly, a concentration of a bias electric field on the drain-side end portion 502 of the gate electrode 5 can be relieved under the non-conduction bias conditions. In such a way, a withstand voltage of the compound semiconductor device 1 can be enhanced.

Moreover, the field plate 6 is arranged between the gate electrode 5 and the drain electrode 4, whereby a curvature of a depletion layer in the drain-side end portion 502 of the gate electrode 5 is controlled, and the bias electric field concentrated on the drain-side end portion 502 is relieved.

Next, a description is made of the case where the compound semiconductor device 1 is in a conduction (ON) state, that is to say, in a channel conduction state. For example, there is considered a case of bias conditions where 600 V is applied to the drain electrode 4, 0 V is applied to the source electrode 3, and an approximate voltage of +3 V to +10 V is applied to the gate electrode 5 (hereinafter, referred to as “conduction bias conditions”). At this time, the same bias voltage as that to the gate electrode 5 is applied to the field plate 6.

Under the conduction bias conditions, the bias voltage approximately ranging from +3 V to +10 V is applied to the field plate 6, and accordingly, the carrier density of the low-conductivity region 210 is increased. Therefore, the conductivity of the low-conductivity region 210 is enhanced, and an increase of an ON-resistance of the compound semiconductor device 1 is suppressed.

In order to increase the carrier density of the low-conductivity region 210 by applying the bias voltage to the field plate 6, it is necessary that the region in the two-dimensional carrier gas layer, where the low-conductivity region 210 is formed, be arranged immediately below the field plate 6. In the case of the conduction bias conditions where a gate voltage, which is substantially the same as the bias voltage applied to the field plate 6, is applied to the gate electrode 5, the low-conductivity region 210 may be formed also in the two-dimensional carrier gas layer 23 immediately below the gate electrode 5. Hence, in the case where the gate electrode 5 and the field plate 6 are connected continuously to each other as illustrated in FIG. 1, the low-conductivity region 210 can be formed below the field plate 6 and the gate electrode 5.

Meanwhile, in such a low-conductivity region above which the field plate 6 is not located, the carrier density cannot be increased also under the conduction bias conditions. As a result, the low-conductivity region concerned is regarded as a resistance component connected between the source electrode and the drain electrode, and an ON-resistance thereof is higher in comparison with that of the compound semiconductor device 1 illustrated in FIG. 1.

As described above, in accordance with the compound semiconductor device 1 according to the first embodiment, the low-conductivity region 210 is arranged in the two-dimensional carrier gas layer 23 immediately below the field plate 6, and accordingly, the concentration of the bias electric field on the drain-side end portion 502 of the gate electrode 5 is relieved under the non-conduction bias conditions. As a result, the withstand voltage of the compound semiconductor device 1 can be enhanced. Moreover, the bias voltage is applied to the field plate 6 under the conduction bias conditions, whereby the carrier density of the low-conductivity region 210 is increased. Therefore, the conductivity of the low-conductivity region 210 is enhanced, and the increase of the ON-resistance of the compound semiconductor device 1 is suppressed.

Hence, in accordance with the compound semiconductor device 1 illustrated in FIG. 1, a compound semiconductor device can be provided, in which the concentration of the bias electric field on the end portion of the gate electrode 5 is relieved, and the increase of the ON-resistance during the time of the operation is suppressed.

By using FIGS. 2 to 9, a description is made below of a manufacturing method of the compound semiconductor device according to the first embodiment. Note that the manufacturing method of the compound semiconductor device, which is mentioned below, is merely an example, and it is a matter of course that the compound semiconductor device is realizable by a variety of manufacturing methods other than the manufacturing method concerned, the variety including modification examples thereof.

(i) As illustrated in FIG. 2, by the MOCVD method and the like, the buffer layer 11, the carrier travel layer 21 and the carrier supply layer 22 are epitaxially grown in this order on the substrate 10. The buffer layer 11 has, for example, the structure in which the AlN layer and the GaN layer are alternately stacked on each other. The carrier travel layer 21 is, for example, the undoped GaN film. The carrier supply layer 22 is made of the nitride semiconductor, which has a larger band gap than that of the carrier travel layer 21, and is different in lattice constant from the carrier travel layer 21. For example, the undoped AlGaN film is employable for the carrier travel layer 21.

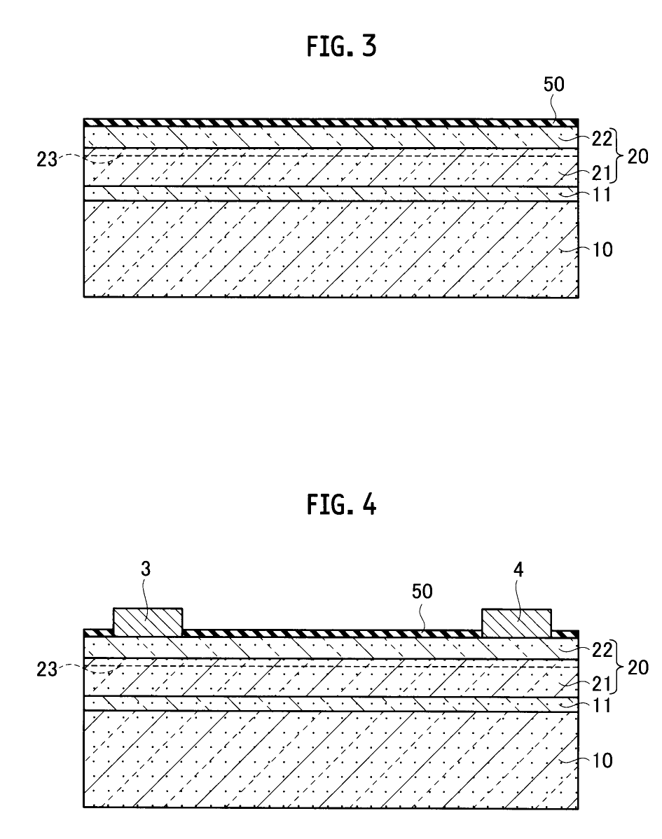

(ii) As illustrated in FIG. 3, on the carrier supply layer 22, the gate insulating film 50 is formed, which is made of a silicon oxide (SiO₂) film, a silicon nitride (SiN) film, an aluminum oxide (Al₂O₃) film, or the like. The gate insulating film 50 is, for example, an Al₂O₃ film with a film thickness of 10 nm.

(iii) By using a photolithography technology, the opening portions are formed at predetermined positions of the gate insulating film 50. Specifically, the gate insulating film 50 located at positions at which the source electrode 3 and the drain electrode 4 are to be arranged is removed by etching by using a photoresist film as a mask.

(iv) By a sputtering method, a stacked film of a Ti film with a film thickness of approximately 25 nm and an Al film with a film thickness of approximately 300 nm is formed on the photoresist film so as to fill the opening portions of the gate insulating film 50. Thereafter, by a lift-off method for moving the photoresist film, a part of the stacked film of the Ti film and the Al film is removed. In such a way, as illustrated in FIG. 4, the source electrode 3 and the drain electrode 4 are formed, each of which has the structure in which the Ti film and the Al film are stacked on each other.

(v) Ohmic sintering is performed so that the source electrode 3 and the drain electrode 4 can be brought into low resistance contact with the two-dimensional carrier gas layer 23.

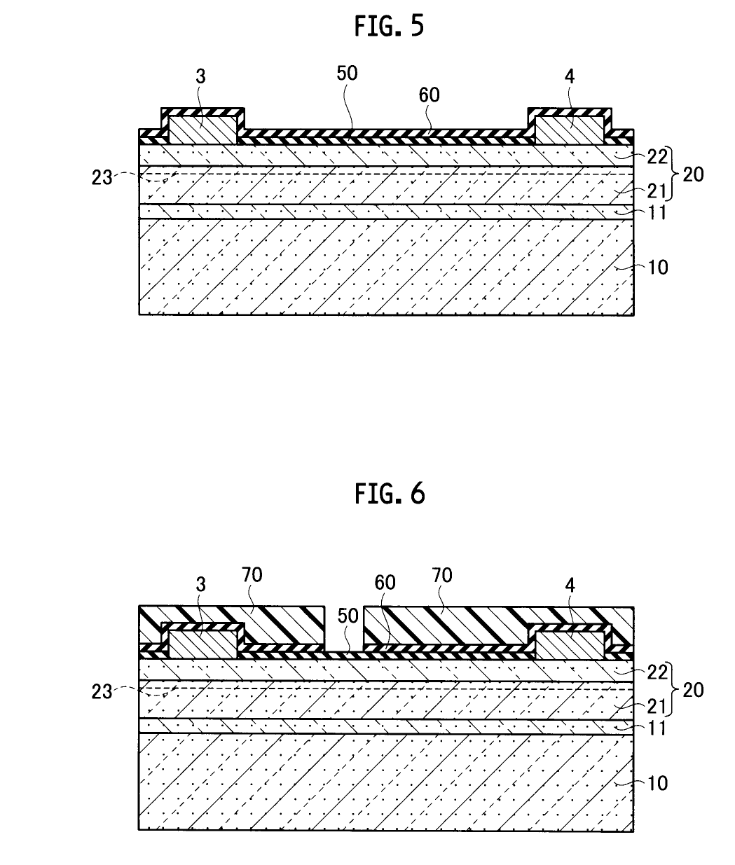

(vi) As illustrated in FIG. 5, the field insulating film 60 made, for example, of silicon oxide (SiO) is formed on the gate insulating film 50, the source electrode 3 and the drain electrode 4. The film thickness of the field insulating film 60 is, for example, approximately 10 nm.

(vii) By using the photolithography technology, the opening portion is formed at a predetermined position of the field insulating film 60. Specifically, as illustrated in FIG. 6, the field insulating film 60 located at a position at which the gate electrode 5 is to be arranged is removed by etching by using a photoresist film 70 as a mask. At this time, the gate insulating film 50 functions as an etching stopper.

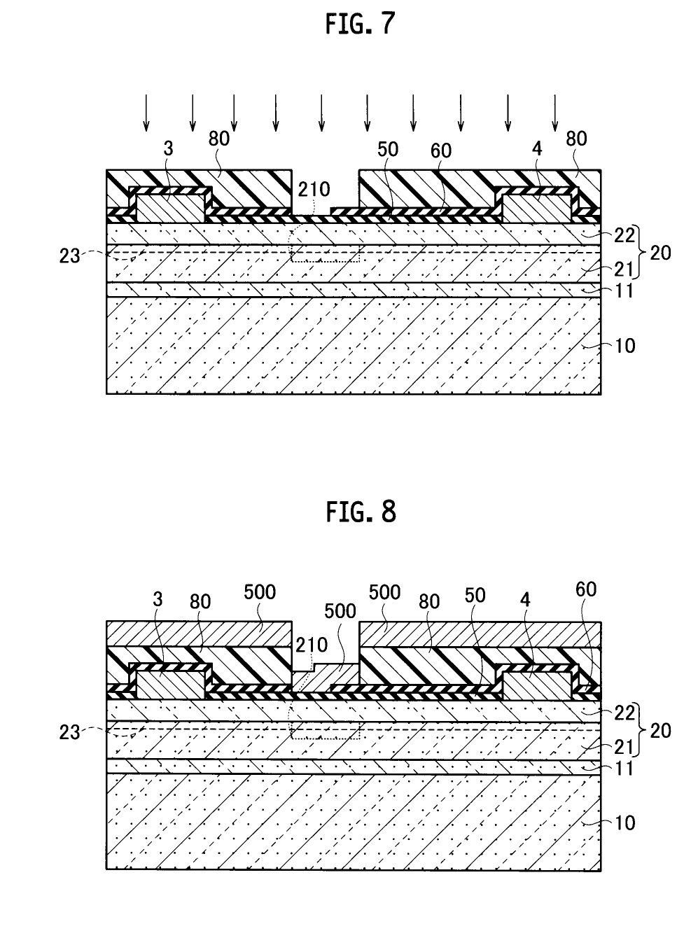

(viii) After the photoresist film 70 is removed, a new photoresist film 80 is formed on the field insulating film 60. The photoresist film 80 located at the positions at which the gate electrode 5 and the field plate 6 are to be arranged is selectively removed, then as illustrated in FIG. 7, nitrogen (N) ions are implanted into the carrier travel layer 21 by using the photoresist film 80 as a mask. Implantation conditions of the nitrogen (N) ions are, for example, that implantation energy is 20 to 40 keV, and that a dosage amount is 1×10¹¹ ion/cm² to 1×10¹³ ion/cm². In such a way, within the region where the two-dimensional carrier gas layer 23 is formed, the low-conductivity region 210 is formed in the region immediately below the field plate 6 and the gate electrode 5.

(ix) On the photoresist film 80, and on the gate insulating film 50 and the field insulating film 60, which are exposed on a bottom surface of the opening portion formed in the photoresist film 80, an Ni film with a film thickness of approximately 100 nm is formed. Moreover, an Au film with a film thickness of approximately 200 nm is formed on the Ni film by the sputtering method. In such a way, as illustrated in FIG. 8, a conductor layer 500 in which the Ni film and the Au film are stacked on each other is formed. The conductor layer 500 formed on the gate insulating film 50 is the metal layer 51 of the gate electrode 5, and the conductor layer 500 formed on the field insulating film 60 is the field plate 6. By removing the photoresist film 80, the compound semiconductor device illustrated in FIG. 1 is completed.

As described above, in accordance with the manufacturing method of the compound semiconductor device according to the first embodiment, the compound semiconductor device 1 is obtained, which includes the low-conductivity region 210, the low-conductivity region 210 being lower in conductivity than the region above which the field plate 6 and the gate electrode 5 are not arranged, in the region immediately below the field plate 6 and the gate electrode 5 within the region of the carrier travel layer 21, where the two-dimensional carrier gas layer 23 is formed. In such a way, the compound semiconductor device 1 can be provided, in which the concentration of the bias electric field on the end portion of the gate electrode 5 is relieved, and the increase of the ON-resistance during the time of the operation is suppressed.

### Modification Examples

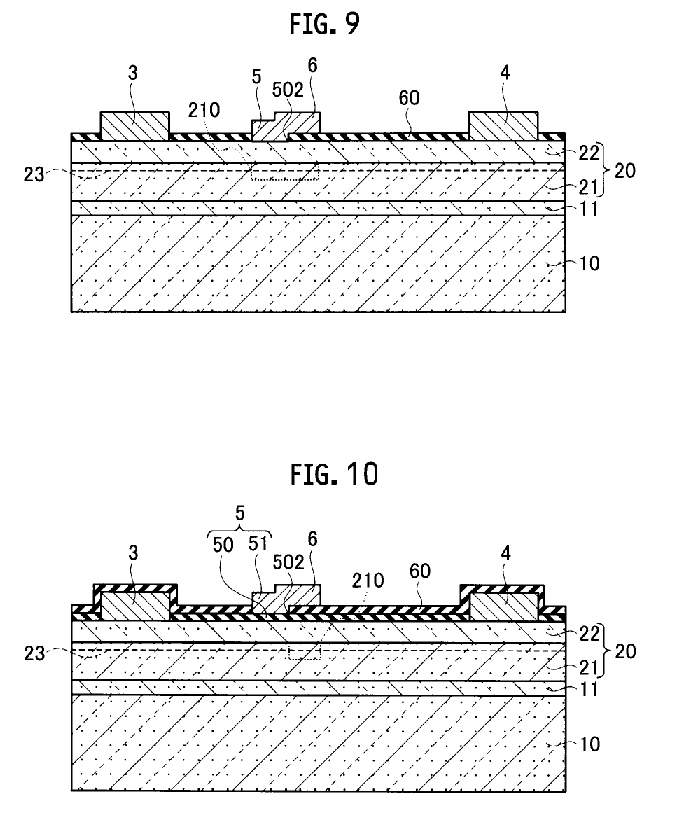

The gate electrode structure of the compound semiconductor device 1 illustrated in FIG. 1 is the MIS structure. However, the gate electrode structure of the compound semiconductor device 1 may be a MES structure in which the gate electrode 5 and the compound semiconductor layer 20 are subjected to Schottky junction. FIG. 9 illustrates an example where the structure of the gate electrode 5 is a structure having only the metal layer 51 without the gate insulating film.

Moreover, as illustrated in FIG. 10, the compound semiconductor device 1 may be configured so that the low-conductivity region 210 cannot be present immediately below the gate electrode 5, and that the low-conductivity region 210 can be present only immediately below the field plate 6. That is to say, the low-conductivity region 210 is not formed in the region above which the field plate 6 is not arranged. Also in the compound semiconductor device 1 illustrated in FIG. 10, the concentration of the bias electric field on the drain-side end portion 502 of the gate electrode 5 can be relieved. Then, by applying an appropriate bias voltage to the field plate 6, the carrier density in the low-conductivity region 210 can be increased, and the increase of the ON-resistance of the compound semiconductor device 1 can be suppressed.

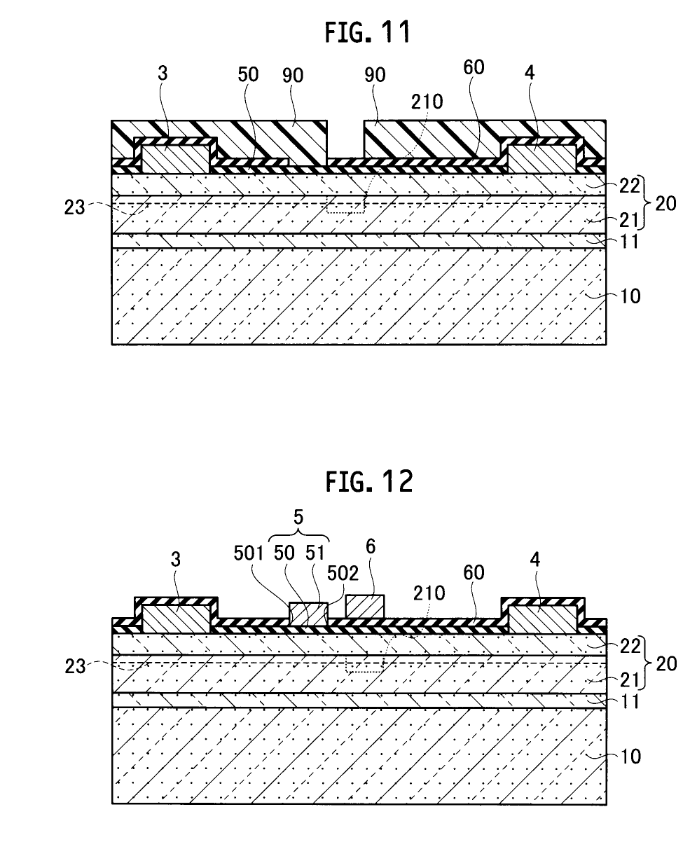

For example, besides the photoresist film 80 illustrated in FIG. 7, which is for forming the gate electrode 5 and the field plate 6, a photoresist film 90 as an ion implanting mask, which is as illustrated in FIG. 11, is used, whereby the compound semiconductor device 1 illustrated in FIG. 10 can be formed.

Moreover, as illustrated in FIG. 12, the compound semiconductor device 1 may be configured so that the gate electrode 5 and the field plate 6 cannot be connected continuously to each other. In the compound semiconductor device 1 illustrated in FIG. 12, the same voltage may be applied to the gate electrode 5 and the field plate 6, and a bias voltage different from the gate voltage applied to the gate electrode 5 may be applied to the field plate 6.

For example, in some case, the bias voltage applied to the field plate 6, which is necessary in order to enhance the conductivity of the low-conductivity region 210, is larger than the gate voltage necessary to turn the compound semiconductor device 1 to a conduction state. As illustrated in FIG. 12, it is made possible to apply such different voltages to the gate electrode 5 and the field plate 6, whereby the bias voltage necessary in order to enhance the conductivity of the low-conductivity region 210 can be applied to the field plate 6 without applying an unnecessarily large gate voltage to the gate electrode 5.

By using the photoresist film 90 for the ion implantation, which is illustrated in FIG. 11, the low-conductivity region 210 can be formed only immediately below the field plate 6 as illustrated in FIG. 12. Moreover, in the photoresist film 80 illustrated in FIGS. 7 and 8, opening portions are individually formed at the position at which the gate electrode 5 is formed and at the position at which the field plate 6 is formed, whereby the compound semiconductor device 1 illustrated in FIG. 12, in which the gate electrode 5 and the field plate 6 are arranged apart from each other, can be manufactured.

### Second Embodiment

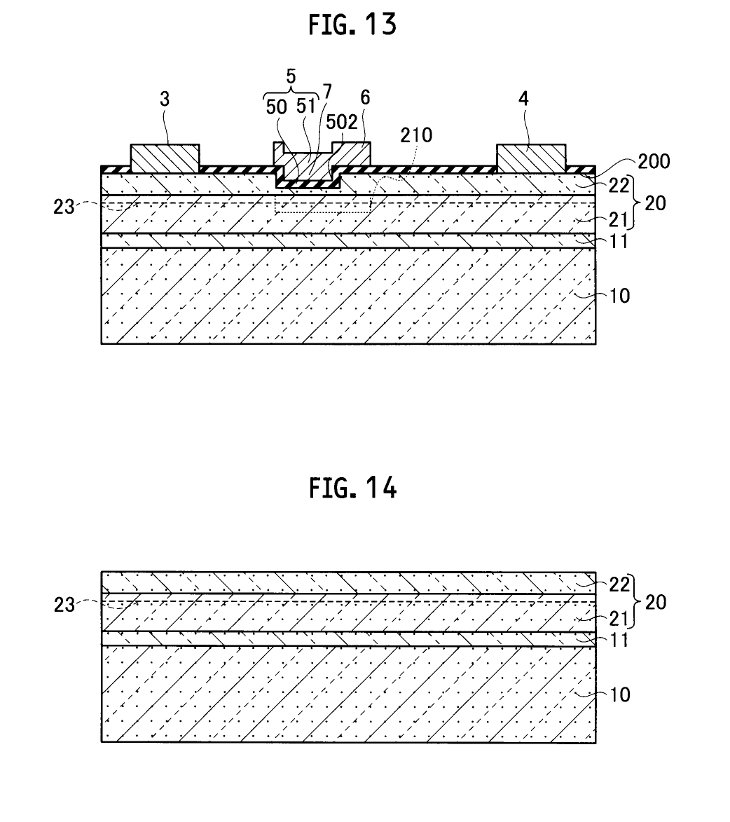

As illustrated in FIG. 13, a compound semiconductor device 1 according to the second embodiment is different from that illustrated in FIG. 1 in that the gate electrode 5 is arranged on a bottom surface of a recessed portion (recess) 7 formed on the principal surface 200 of the compound semiconductor layer 20. Moreover, the gate insulating film 50 located under the field plate 6 functions as a field insulating film. Other configurations are similar to those of the first embodiment illustrated in FIG. 1.

As illustrated in FIG. 13, a part of an upper surface of the carrier supply layer 22 is etched, and the recessed portion 7 is formed. The recessed portion 7 is formed so that a depth thereof can be shallower than the thickness of the carrier supply layer 22. For example, in the case where the thickness of the carrier supply layer 22 is approximately 20 μm, the depth of the recessed portion approximately ranges from 5 to 10 μm.

Also in the compound semiconductor device 1 illustrated in FIG. 13, the low-conductivity region 210 is arranged in the two-dimensional carrier gas layer 23 located immediately below the field plate 6 and the gate electrode 5, and accordingly, the concentration of the bias electric field on the drain-side end portion 502 of the gate electrode 5 can be relived under the non-conduction bias conditions. In such a way, the withstand voltage of the compound semiconductor device 1 can be enhanced. Moreover, the field plate 6 is arranged between the gate electrode 5 and the drain electrode 4, whereby the curvature of the depletion layer in the drain-side end portion 502 of the gate electrode 5 is controlled, and the bias electric field concentrated on the drain-side end portion 502 is relieved.

Moreover, the bias voltage is applied to the field plate 6 under the conduction bias conditions, whereby the carrier density of the low-conductivity region 210 is increased. Therefore, the conductivity of the low-conductivity region 210 is enhanced, and the increase of the ON-resistance of the compound semiconductor device 1 is suppressed.

Others are substantially similar to those of the first embodiment, and a duplicate description is omitted. For example, the gate electrode structure of the compound semiconductor device 1 may be not the MIS structure but the MES structure. Moreover, in a similar way to the compound semiconductor device 1 illustrated in FIG. 10, the low-conductivity region 210 does not have to be present immediately below the gate electrode 5. Furthermore, in a similar way to the compound semiconductor device 1 illustrated in FIG. 12, the gate electrode 5 and the field plate 6 do not have to be connected continuously to each other.

By referring to FIGS. 14 to 19, a description is made of a manufacturing method of the compound semiconductor device 1 according to the second embodiment. Note that the manufacturing method of the compound semiconductor device 1, which is mentioned below, is merely an example, and it is a matter of course that the compound semiconductor device 1 is realizable by a variety of manufacturing methods other than the manufacturing method concerned, the variety including modification examples thereof

(i) As illustrated in FIG. 14, by the MOCVD method and the like, the buffer layer 11, the carrier travel layer 21 and the carrier supply layer 22 are epitaxially grown in this order on the substrate 10. The carrier supply layer 22 is made of the nitride semiconductor, which has a larger band gap than that of the carrier travel layer 21, and is different therefrom in lattice constant.

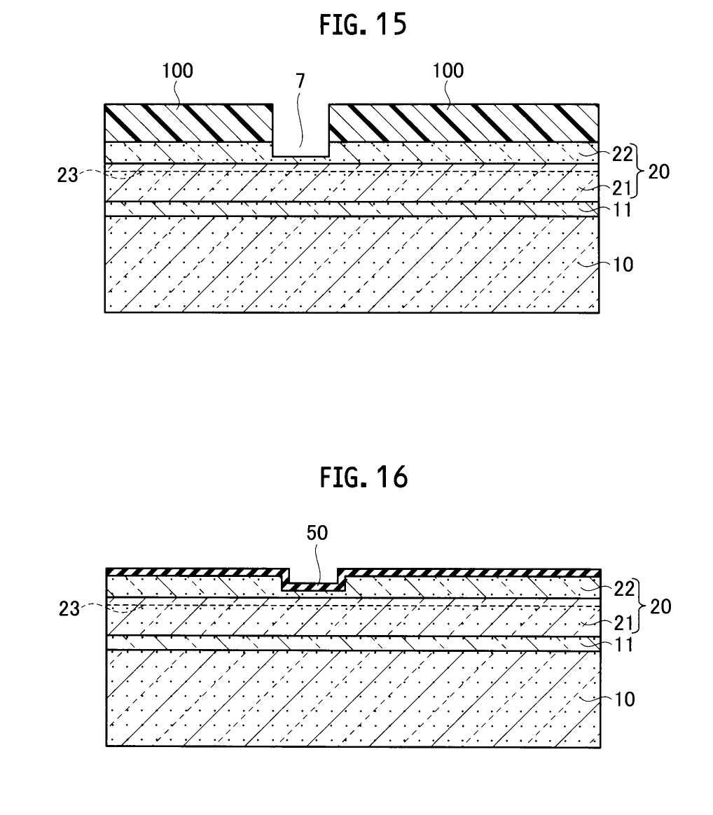

(ii) After a photoresist film 100 is formed on the carrier supply layer 22, the photoresist film 100 located at the position at which the gate electrode 5 is to be arranged is removed by etching. Thereafter, by using the photoresist film 100 as an etching mask, a part of the upper portion of the carrier supply layer 22 is selectively removed by etching, and the recessed portion 7 is formed as illustrated in FIG. 15.

(iii) After the photoresist film 100 is removed, the gate insulating film 50 is formed on the carrier supply layer 22 so as to cover a bottom surface and inner wall of the recessed portion 7 as illustrated in FIG. 16.

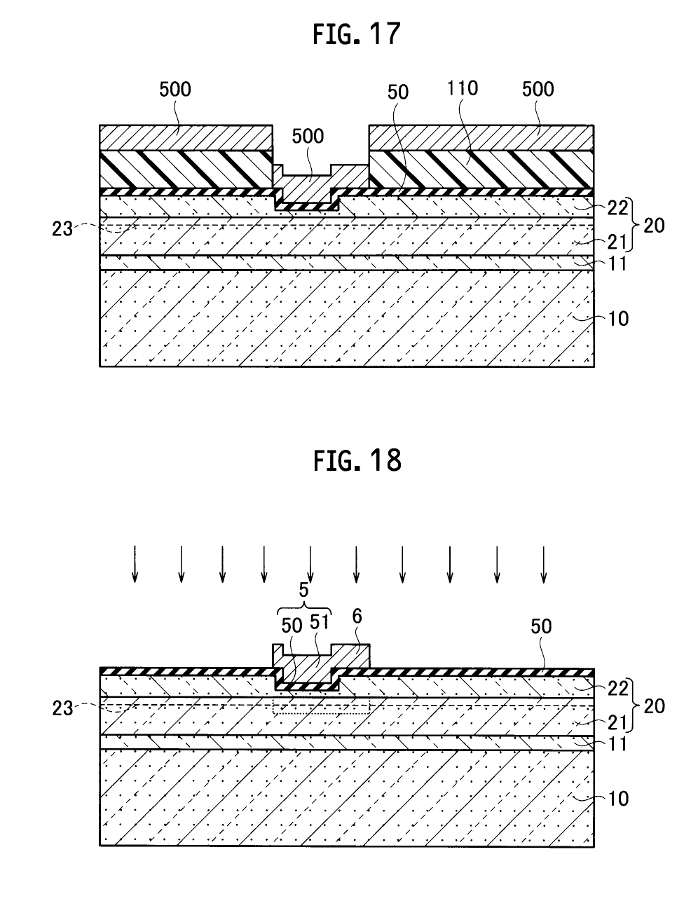

(iv) After a photoresist film 110 is formed on the gate insulating film 50, the photoresist film 110 located at a position at which the gate electrode 5 and the field plate 6 are to be arranged is removed by etching. Thereafter, as illustrated in FIG. 17, a conductor layer 500 is formed on the photoresist film 110, and on the gate insulating film 50 exposed on a bottom surface of such an opening portion of the photoresist film 110. The conductor layer 500 is, for example, a stacked body of a Ni film and an Au film. By removing the photoresist film 110, the metal layer 51 of the gate electrode 5 and the field plate 6 are formed.

(v) After the photoresist film 110 is removed, then as illustrated in FIG. 18, silicon (Si) ions are implanted into the carrier supply layer 22 by using the gate electrode 5 and the field plate 6 as masks. Implantation conditions of the silicon (Si) ions are, for example, that implantation energy is 10 to 30 keV, and that a dosage amount is 1×10¹⁴ ion/cm² to 1×10¹⁶ ion/cm². In such a way, the conductivity of the region, which is located immediately below the gate electrode 5 and the field plate 6, and where the two-dimensional carrier gas layer 23 is formed, becomes lower than that of the region adjacent thereto. That is to say, the low-conductivity region 210 is formed immediately below the field plate 6 and the gate electrode 5.

(vi) After a new photoresist film 120 is formed, the photoresist film 120 located at the positions at which the source electrode 3 and the drain electrode 4 are to be arranged is removed. Then, the gate insulating film 50 located at the positions at which the source electrode 3 and the drain electrode 4 are to be arranged is removed by etching by using the photoresist film 120 as a mask.

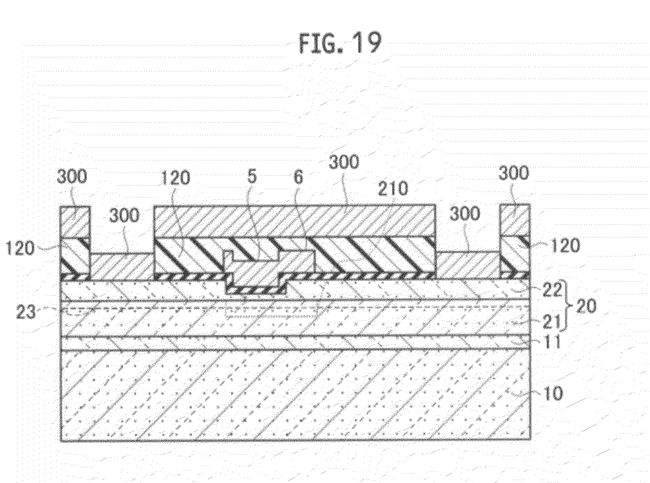

(vii) As illustrated FIG. 19, a stacked film 300 of a Ti film and an Al film is formed on the photoresist film 120 so as to fill the opening portions of the gate insulating film 50. Thereafter, by the lift-off method for moving the photoresist film, a part of the stacked film 300 of the Ti film and the Al film is removed. In such a way, the source electrode 3 and the drain electrode 4 are formed, each of which has the structure in which the Ti film and the Al film are stacked on each other.

(viii) Ohmic sintering is performed so that the source electrode 3 and the drain electrode 4 can be brought into low resistance contact with the two-dimensional carrier gas layer 23. By the above-described procedure, the compound semiconductor device 1 illustrated in FIG. 13 is obtained.

### Other Embodiments

As described above, the present invention has been described by the first and second embodiments; however, it should not be understood that the description and the drawings, which forms part of this disclosure, limit this invention. From this disclosure, varieties of alternative embodiments, examples and application technologies will be made obvious for those skilled in the art. For example, the compound semiconductor device 1 may be either a normally-off type transistor or a normally-on type transistor.

As described above, it is a matter of course that the present invention incorporates varieties of embodiments and the like, which are not described here. Hence, the technical scope of the present invention is defined only by items which specify the invention, and are according to the scope of claims reasonable from the above description.

What is claimed is:

1. A compound semiconductor device comprising:
a compound semiconductor layer including a carrier supply layer and a carrier travel layer in which a two-dimensional carrier gas layer is formed in a vicinity of an interface with the carrier supply layer;
a source electrode arranged on a principal surface of the compound semiconductor layer;
a drain electrode arranged on the principal surface of the compound semiconductor layer;
a gate electrode arranged on the principal surface between the source electrode and the drain electrode;
a field plate arranged above the principal surface between the gate electrode and the drain electrode; and
a low-conductivity region arranged within a region immediately below the field plate in a region where the two-dimensional carrier gas layer is formed, the low-conductivity region having lower conductivity than a region above which the field plate or the gate electrode is not arranged in the region where the two-dimensional carrier gas layer is formed.

2. The compound semiconductor device according to claim 1, wherein
the gate electrode includes a gate insulating film brought into contact with the principal surface of the compound semiconductor layer.

3. The compound semiconductor device according to claim 1, wherein
the gate electrode is arranged on a bottom surface of a recessed portion formed in the principal surface of the compound semiconductor layer.

4. The compound semiconductor device according to claim 1, wherein
the low-conductivity region is provided in a region immediately below the gate electrode, the region having the two-dimensional carrier gas layer formed therein.

5. The compound semiconductor device according to claim 1, wherein
the gate electrode and the field plate are connected continuously to each other.
